(19) United States
(12) Patent Application Publication
(10) Pub. No.: US 2008/0305409 A1
(43) Pub. Date: Dec. 11, 2008

(54) LITHOGRAPHIC MASK AND METHOD FOR PRINTING FEATURES USING THE MASK

(76) Inventor: Shane R. Palmer, Austin, TX (US)

Correspondence Address: TEXAS INSTRUMENTS INCORPORATED, P O BOX 655474, M/S 3999, DALLAS, TX, 75265, US

(21) Appl. No.: 11/760,430

(22) Filed: Jun. 8, 2007

(51) Int. Cl. G03F 1/16; G03F 7/20

(52) U.S. Cl. 430/5; 430/311

(57) ABSTRACT

A lithographic mask enables printing wafer features at very small to large pitch values with an increase in the depth of focus. The mask may include square or rectangular patterns for printing square or rectangular features, such as contacts or vias. The square or rectangular features include wings that aid in the transfer of the square or rectangular features. The mask may be used to print water features by exposing the mask to radiation with selective polarization.

### FIELD

This invention relates generally to semiconductor fabrication.

### BACKGROUND

In the semiconductor industry, intricate designs or patterns of electronic chips and integrated circuits (IC) are generally made using lithographic techniques, such as photolithography, X-ray lithography, or extreme ultraviolet (EUV) lithography. These techniques utilize a patterned photomask or reticle in combination with certain systems to transfer patterns onto objects such as semiconductor wafers and electronic chips. For example, in a photolithographic process, a patterned photomask is used in combination with laser exposure systems to transfer patterns. Processing situations, however, may distort the resulting pattern defined on a semiconductor wafer. For example, optical diffraction may cause the pattern defined on the wafer to differ from the pattern of the photomask.

Of the patterns that are printed in IC manufacturing, the contact and vias are perhaps the most difficult to print. This is due to the nature of printing the square or rectangular features of the contact or vias. For small features on a four times (4×) or five times (5×) mask, the square features have a diffraction pattern that behaves nearly the same as the transparent “hole” or first order Bessel function. This transparent hole may be given by the equation:

$$I \sim {{I}_{0} [ \frac{2 {J}_{1} ( kaw )}{( kaw )} ]}^{2}$$

As such, the contact pattern produces larger diffraction angles, which requires a larger lens angle capture (or higher numerical aperture (NA)) and larger angles at image reconstruction The large angles, however, reduce the depth of focus.

Additionally, the square or rectangular features do not lend to polarization methods to improve resolution. Both the transverse electric field (TE) and transverse magnetic field (TM) polarization modes transmit equally. The use of TM mode is not desirable at the imaging plane as it creates a loss of contrast.

A photomask may also include different types of assist or auxiliary features that compensate for distortions in a resulting pattern transferred onto a wafer. FIGS. 1A-1C are diagrams illustrating several different types of assist features utilized in transferring a square or rectangular features, such as contacts or vias, onto a wafer.

FIG. 1A illustrates a contact pattern 102 which has been sized or “biased.” The drawback in sizing a contact pattern is that, for the 35 nm half-pitch node a 4× contact pattern with a 40 nm target, the pattern is less than the illuminating wavelength. This may impact the intensity of the radiation transferred onto the wafer. A large bias, however, degrades the contrast and reduces the mask-error factor.

FIG. 1B illustrates a contact pattern 104 that includes serifs 106. Serifs 106 are added to the outside corner of the feature. FIG. 1C illustrates a contact pattern 108 that includes outriggers 110. The serifs 106 and outriggers 110 aid in the transfer of contact patterns. These auxiliary features, however, do not lend to polarization methods to improve resolution.

Accordingly, it is desirable to create assist features that allows use of polarizations with an increase to the depth of focus over a large pitch ranges and that increases the resolution of the transferred pattern.

### SUMMARY

An embodiment of the present disclosure is directed to a lithographic mask. The mask comprises a square pattern for printing a square feature on a semiconductor wafer and a plurality of wing patterns positioned adjacent to each side of the square pattern. The plurality of wing patterns aid in the transfer of the square pattern onto the semiconductor wafer.

Another embodiment is directed to a lithographic mask. The mask comprises a rectangular pattern for printing a rectangular feature on a semiconductor wafer and a plurality of wing patterns positioned adjacent to each side of the rectangular pattern. The plurality of wing patterns aid in the transfer of the rectangular pattern onto the semiconductor wafer.

Another embodiment is directed to a method of printing a semiconductor feature onto a semiconductor wafer. The method comprises placing a lithographic mask in a lithographic apparatus. The lithographic mask comprises at least one pattern for printing a feature on the semiconductor wafer and a plurality of wing patterns positioned adjacent to each side of the at least one pattern. The method also comprises exposing the lithographic mask to polarized radiation to transfer the at least one pattern onto the semiconductor wafer.

Additional embodiments of the disclosure will be set forth in part in the description which follows, and in part will be obvious from the description, or may be learned by practice of the present disclosure. The embodiments of the disclosure will be realized and attained by means of the elements and combinations particularly pointed out in the appended claims.

It is to be understood that both the foregoing general description and the following detailed description are exemplary and explanatory only and are not restrictive of the invention, as claimed

### BRIEF DESCRIPTION OF THE DRAWINGS

The accompanying drawings, which are incorporated in and constitute a part of this specification, illustrate embodiments of the disclosure and together with the description, serve to explain the principles of the embodiments.

FIGS. 1A-1C are diagrams illustrating several conventional assist features in a lithographic mask.

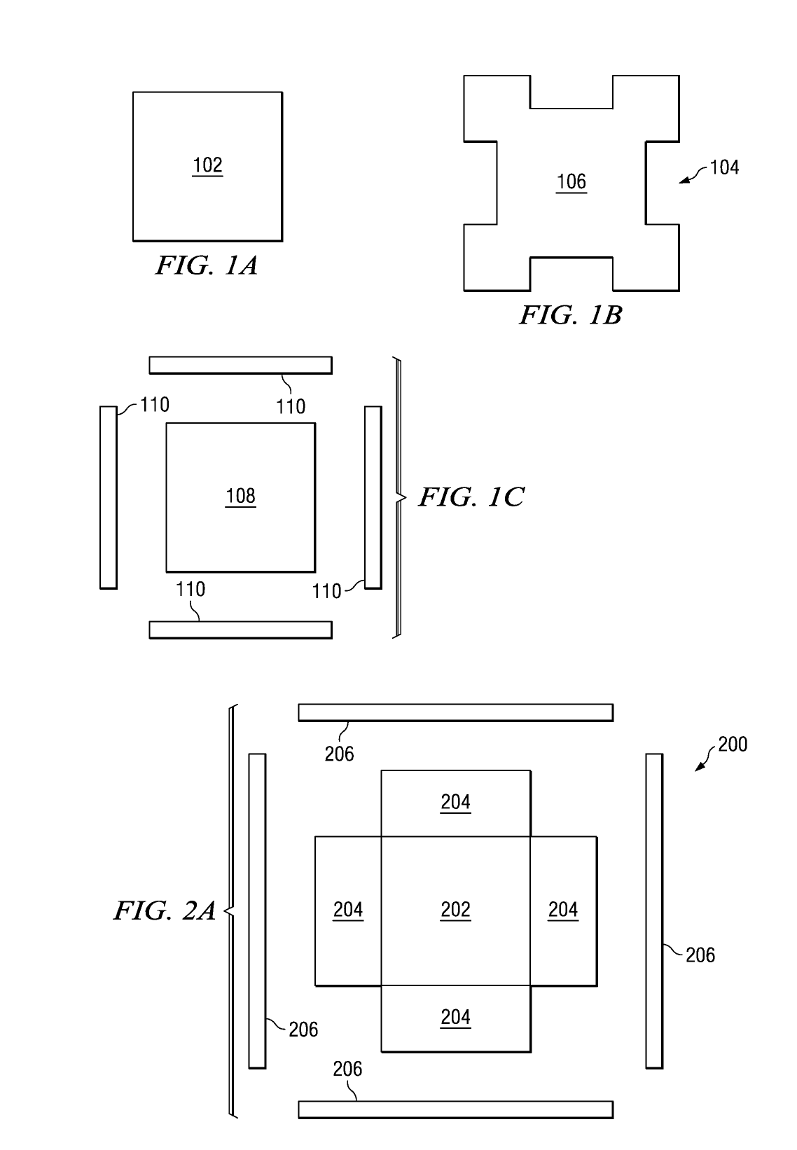

FIGS. 2A and 2B are diagrams illustrating assist features consistent with embodiments of the present disclosure.

FIG. 3 is a diagram illustrating depth of focus data for an exemplary mask pattern consistent with embodiment of the present disclosure.

FIGS. 4A and 4B are diagrams illustrating depth of focus for an exemplary mask pattern consistent with embodiment of the present disclosure.

FIGS. 5A and 5B are diagrams illustrating depth of focus and exposure threshold for an exemplary mask pattern consistent with embodiments of the present disclosure.

### DETAILED DESCRIPTION

Embodiments of the present disclosure are directed to a lithographic mask to enable printing wafer features at very small to large pitch values with an increase in the depth of focus. The mask may include square or rectangular patterns for printing square or rectangular features, such as contacts or vias. The square or rectangular features include wings that aid in the transfer of the square or rectangular features. The square or rectangular patterns with wings provide a smaller angular dispersement of the diffraction orders and improved collection by the lens in a lithographic process. Additionally, square or rectangular patterns with wings provide increased depth of focus and resolution in printing the features.

Additionally, embodiments of the present disclosure are directed to methods of printing water features by exposing the mask to radiation with selective polarization. To transfer the wafer features, the mask is illuminated with polarized radiation, such as TE, TM, or azimuthal mode polarization. The use of polarization improves the contrast at the wafer and prints the features with an increased depth of focus.

Reference will now be made in detail to the exemplary embodiments of the present disclosure, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments which may be practiced. These embodiments are described in sufficient detail to enable those skilled in the art to practice the embodiments and it is to be understood that other embodiments may be utilized and that changes may be made without departing from the scope of the invention. The following description is, therefore, merely exemplary.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

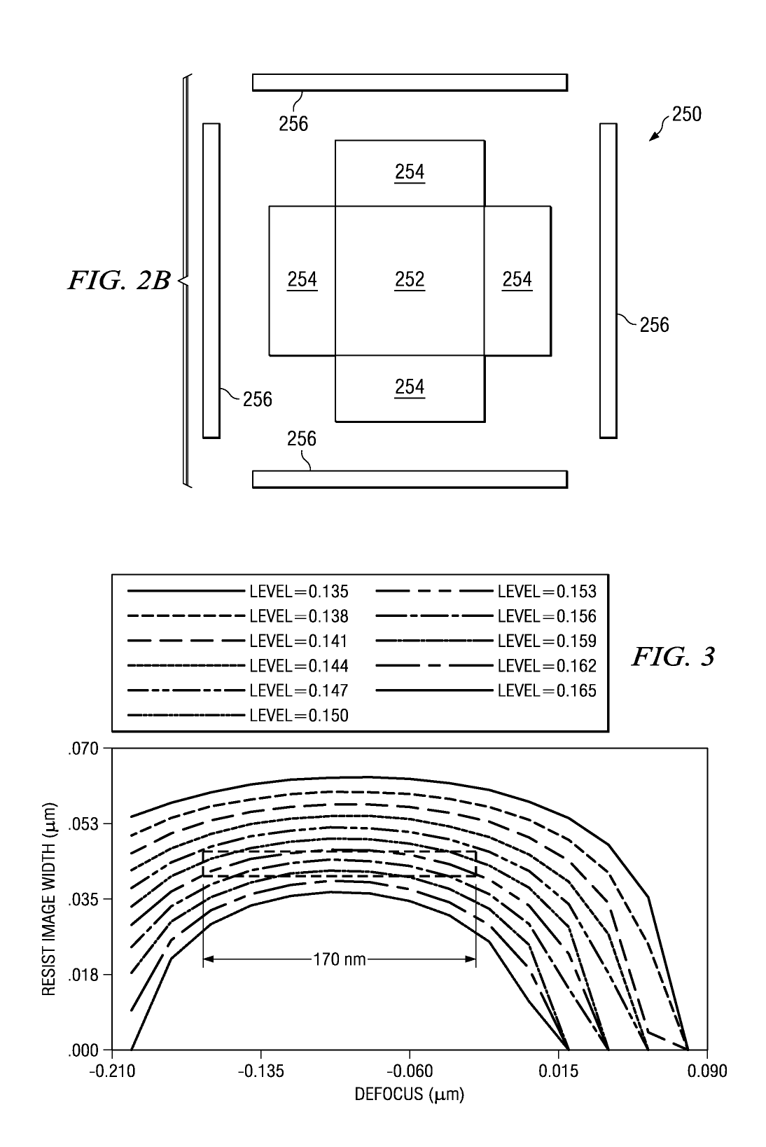

FIG. 2A is a diagram illustrating a mask pattern 200 consistent with embodiments of the present disclosure. As illustrated, mask pattern 200 includes a square pattern 202, wings 204, and outriggers 206. One skilled in the art will realize that FIG. 2 is a general diagram illustrating one square feature and that pattern 200 may be part of a lithographic mask that includes additional features.

As illustrated in FIG. 2A, square pattern 202 may be created from two perpendicular intersecting rectangular spaces. The intersecting portions of the rectangular spaces define square pattern 202. Square pattern 202 represents a square feature, such as a contact, to be printed onto the semiconductor wafer.

The non-intersection portions of the rectangular spaces define wings 204. Wings 204 aid in the transfer of square pattern 202 onto the wafer. Wings 204 aid in the transfer of square pattern 202 by increasing the collection of the diffracted orders that create the hole image from an “overlapping” crossed line pattern. The open spaces (the two crossed transparent lines that create the cross) on the mask has the advantage of exploiting TE polarized waves which favorably interfere and increase contrast at the image plane. Square pattern 202 including wings 204 provides a smaller angular dispersion of the diffraction orders and improved collection by the lens of the lithographic apparatus.

The size of square pattern 202 depends on the size of the square feature to be printed and the lithographic apparatus and parameters used. For example, square pattern 202 may be an even multiple of the size of the square feature, such as a contact, to be printed, for example four times (4×) or five times (5×).

The size of wings 204 depends on the size of square pattern 202 and the lithographic apparatus and parameters used. For example, square features, such as a contact that are printed, are adjusted to match the “common” window of exposure for the lithographic mask. In other words, the length of wings 204 and square pattern 202 may be dependent on the density of the nearby patterns. The balance between the size of wings 204 and the separation distance between any nearby feature patterns is adjusted by an optical proximity correction method to maintain sufficient contrast and intensity.

The size of wings 204 may also be determined by optimizing wings 204 for the particular size of square pattern 202. For example, a particular square pattern 202 may be created for a pattern feature, such as a contact pattern. Then, multiple wings may be simulated for the particular size square pattern to determine the wing size that produces the best transferred pattern.

As illustrated in FIG. 2A, mask 200 may include outriggers 206 to aid in the transfer of square pattern 202. Outriggers 206 aid in the transfer of square pattern 202 by diffracting radiation passing through outriggers 206 and contributing a portion of the diffracted radiation to the transferred square feature. Outriggers 206 may be small enough and properly located in relation to square pattern 202 so that that outriggers 206 are not transferred onto the wafer because outriggers are below the dimensional resolution.

Outriggers 206 may be either shared type or the retained type. The type, size, number, and placement of outriggers 206 may depend on the size of square pattern 202 and the distance or “pitch” between square pattern 202 and additional mask features. Any type of suitable lithographic technique may be utilized to determine the type, size, number, and placement of outriggers 206.

According to embodiments of the present disclosure, mask 200 may be used with a lithography process in which the radiation beam, used to illuminate mask 200, is polarized. Any type of polarization technique may be utilized such as TE polarization and TM polarization. Additionally, mask 200 may be used with a lithography process in which the radiation beam having an azimuthal mode of polarization. Azimuthal mode of polarization may improve the contrast at the wafer and print square feature with an increased depth of focus since the diffracted orders follow from a space feature rather than a square feature.

Mask 200 as illustrated above in FIG. 2A includes square pattern 202 and wings 204 arranged in a “plus sign” arrangement in which an axis of square pattern 202 is aligned with an axis of mask 200. According to embodiments of the present disclosure, square pattern 202 and wings 204 may be arranged in an “x-shaped” arrangement in which an axis of square pattern 202 is misaligned with an axis of mask 200. The cross arrangement may be achieved by rotating square pattern 202, wings 204, and optionally outrigger 206 by 45 degrees. By utilizing the cross arrangement, mask 200 may effectively reduce the pitch value that can be achieved to 64 nm.

Mask 200 as illustrated in FIG. 2A includes square pattern 202 for printing a square feature such as a contact. According to embodiments of the present disclosure, the mask may also include a rectangular pattern for printing a rectangular shaped wafer features, such as a via. FIG. 2B is a diagram illustrating mask 250 for printing a rectangular feature, such as a via. Mask 250 includes a rectangular pattern 252, wings 254, and outriggers 256. One skilled in the art will realize that FIG. 2B is a general diagram illustrating one rectangular feature and that pattern 250 may be part of a lithographic mask that includes additional features.

As illustrated in FIG. 2B, rectangular pattern 252 may be created from two perpendicular intersecting rectangular spaces. The first rectangular space may have a length longer than the second rectangular space in order to create rectangular pattern 252. The intersecting portions of the rectangular spaces define rectangular pattern 252. Rectangular pattern 252 represents a rectangular feature, such as a via, to be printed onto the wafer.

The non-intersection portions of the rectangular spaces define wings 254. Wings 254 aid in the transfer of rectangular pattern 252 onto the wafer. Wings 254 aid in the transfer of rectangular pattern 252 by increasing the collection of the diffracted orders that create the hole image from an “overlapping” crossed line pattern. The open spaces (the two crossed transparent lines that create the cross) on the mask has the advantage of exploiting TE polarized waves which favorably interfere and increase contrast at the image plane. Rectangular feature 252 including wings 254 provides a smaller angular dispersion of the diffraction orders and improved collection by the lens of the lithographic apparatus.

The size of rectangular pattern 252 depends on the size of the rectangular pattern to be printed and the lithographic apparatus and parameters used. For example, rectangular pattern 252 may be an even multiple of the size of the rectangular feature, such as a via, be printed, for example four times (4×) or five times (5×).

The size of wings 254 depends on the size of rectangular pattern 252 and the lithographic apparatus and parameters used. For example, rectangular features, such as a vias that are printed, are adjusted to match the “common” window of exposure for the lithographic mask. In other words, the length of wings 254 and rectangular pattern 252 may be dependent on the density of the nearby patterns. The balance between the size of wings 254 and the separation distance between any nearby feature patterns is adjusted by an optical proximity correction method to maintain sufficient contrast and intensity.

The size of wings 254 may also be determined by optimizing wings 254 for the particular size of rectangular pattern 252. For example, a particular rectangular pattern 252 may be created for a pattern feature, such as a via pattern. Then, multiple wings may be simulated for the particular size rectangular pattern to determine the wing size that produces the best transferred pattern.

As illustrated in FIG. 2B, pattern 250 may include outriggers 256 to aid in the transfer of rectangular pattern 252. Outriggers 256 aid in the transfer of rectangular pattern 252 by diffracting radiation passing though outriggers 256 and contributing a portion of the diffracted radiation to the transferred rectangular feature. Outriggers 256 may be small enough and properly located in relation to rectangular pattern 252 so that that outriggers 256 are not transferred onto the wafer because outriggers are below the dimensional resolution.

Outriggers 256 may be either shared type or the retained type. The type, size, number, and placement of outriggers 256 may depend on the size of rectangular feature 252 and the distance or “pitch” between rectangular pattern 252 and additional mask features. Any type of suitable lithographic technique may be utilized to determine the type, size, number, and placement of outriggers 256.

According to embodiments of the present disclosure, mask 250 may be used with a lithography process in which the radiation beam, used to illuminate mask 250, is polarized. Any type of polarization technique may be utilized such as TE polarization and TM polarization. Additionally, mask 250 may be used with a lithography process in which the radiation beam having an azimuthal mode of polarization. Azimuthal mode of polarization may improve the contrast at the wafer and print rectangular feature with an increased depth of focus since the diffracted orders follow from a space feature rather than a rectangular feature.

Mask 250 as illustrated above in FIG. 2B includes rectangular pattern 252 and wings 254 arranged in a “plus sign” arrangement. According to embodiments of the present disclosure, rectangular feature 252 and wings 254 may be arranged in an “x-shaped” arrangement in which an axis of rectangular pattern 252 is misaligned with an axis of mask 250. The cross arrangement may be achieved by rotating rectangular pattern 252, wings 254, and optionally outrigger 256 by 45 degrees. By utilizing the cross arrangement, mask 250 may effectively reduce the pitch value that can be achieved to 64 nm.

Mask 200 or mask 250 may be used with any type of conventional lithographic apparatus. Further, mask 200 or mask 250 may be used to pattern a semiconductor wafer by any type of suitable lithographic process. For example, mask 200 or mask 250 may be positioned in the lithographic apparatus. Then, the lithographic apparatus is configured to the proper exposure settings. Particularly, the lithographic apparatus is configured to expose mask 200 or mask 250 with polarized radiation as described above. Then, mask 200 or mask 250 is exposed with radiation to transfer square pattern 202 or rectangular pattern 252 onto the wafer.

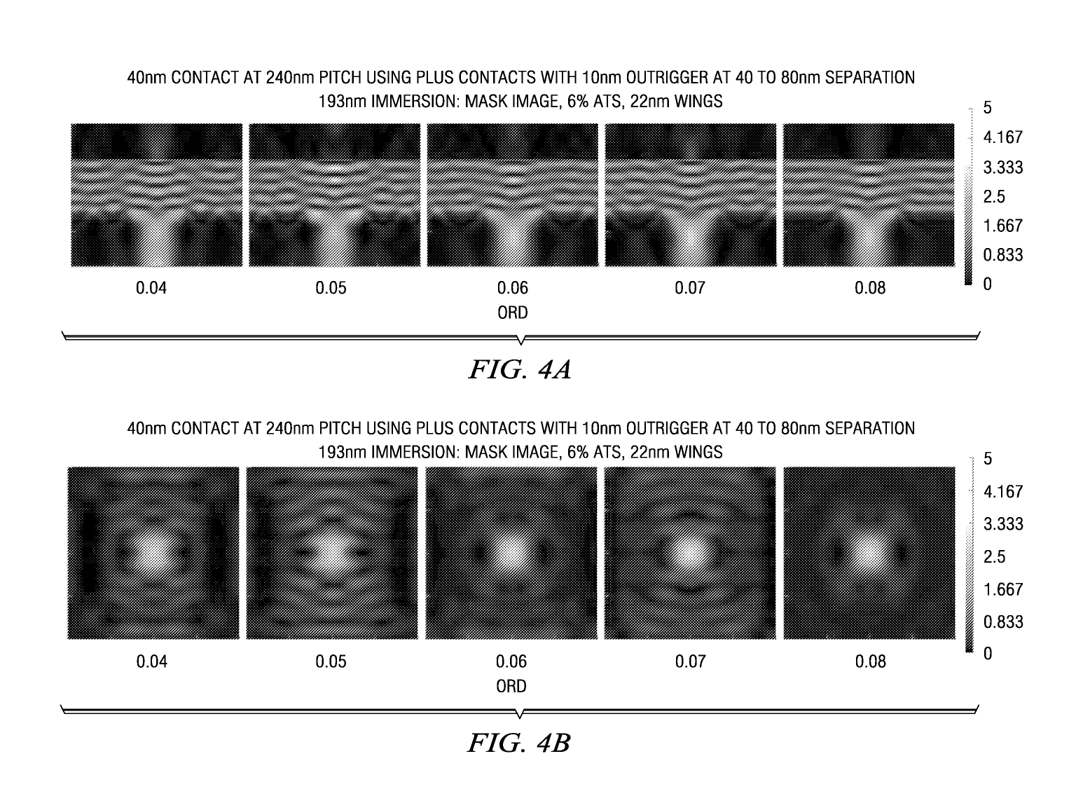

As mentioned above, mask 200 or mask 250 may increase the depth of focus by utilizing wings in combination with a square or rectangular feature. FIG. 3 is a graph illustrating resist image width and defocus data for a contact with a cross wing type consistent with embodiment of the present disclosure.

As mentioned above, the size and position of square pattern 202, wings 204 and outriggers 206, and the lithographic parameters used in exposing the mask 200 may be determined and optimized for the particular wafer feature to be printed. Table 1 includes several examples of the size and position of square pattern 202, wings 204 and outriggers 206, and the lithographic parameters used in exposing the mask 200.

TABLE 1

| | Pattern | | | | Outrigger | | | Wing |
|---|---|---|---|---|---|---|---|---|
| | size | Mask | Pitch | Outrigger | separation | | Wing | width |
| Example | (nm) | Mag. | (nm) | Size (nm) | (nm) | Polarization | Type | (nm) |
| 1 | 40 | 4X | 240 | 10 | 40-80 | azimuthal | cross | 22 |
| 2 | 28 | 4X | 64 | NA | NA | azimuthal | x | 12 |

One skilled in the art will realize that the examples illustrated in Table 1 are exemplary and that square pattern 202, wings 204 and outriggers 206, and the lithographic parameters may be configured in any manner to optimize the transfer of the square pattern onto a semiconductor wafer.

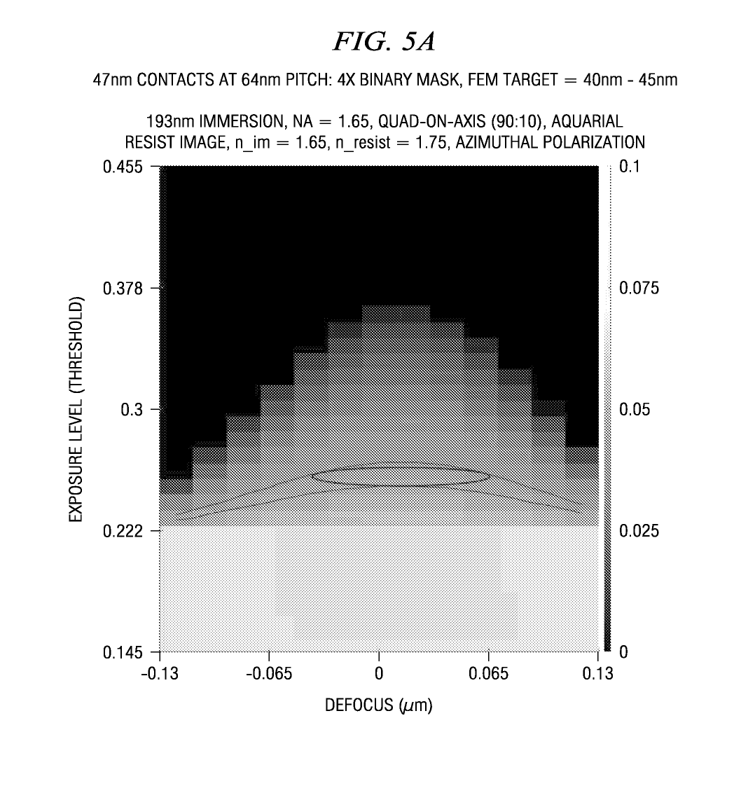

As mentioned above, the rectangular or square pattern including the wings improves the depth of focus and resolution of the printed feature. FIGS. 4A and 4B are diagram illustrating mask transmission for mask 200 configured with the parameters of example 1. As illustrated, mask 200 including wings increases the resolution and depth of focus of the pattern transmission.

FIG. 4A shows the cross section of the transmitted wavefronts from the mask using TE polarized waves incident. The mask represents a sub-wavelength feature to be imaged. Without the use of the wing features this contact would have no transmitted orders from the mask pattern. The placement of the outrigger feature (added open space nearby wing) in increased going from left to right from 40 nm to 80 nm separation.

FIG. 4B similarly shows a top down view of the imaged pattern from the mask and the effect of changing the placement of the outrigger separation (from the edge of the wings).

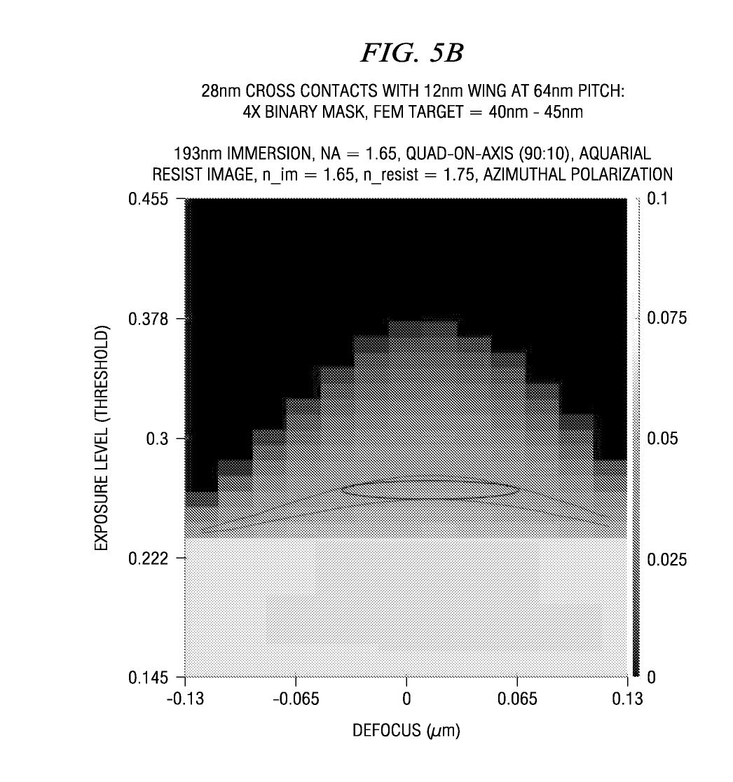

FIGS. 5A and 5B are two diagrams illustrating the depth of focus and exposure threshold for a conventional biased contact and for a mask 200 configured with the parameters of example 2. FIG. 5A illustrates the depth of focus and exposure threshold for a conventional biased contact. FIG. 5B illustrates the depth of focus and exposure threshold for a mask 200 configured with the parameters of example 2. As illustrated, mask 200 including wings has an improved depth of focus and exposure when compared to a conventional biased contact.

Other embodiments of the present disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A lithographic mask, comprising:
a square pattern for printing a square feature on a semiconductor wafer; and
a plurality of wing patterns positioned adjacent to each side of the square pattern, wherein the plurality of wing patterns aid in the transfer of the square pattern onto the semiconductor wafer.

2. The mask of claim 1, further comprising:
outriggers positioned adjacent to the square pattern, wherein the outriggers aid in the transfer of the square pattern.

3. The mask of claim 1, wherein the square pattern and the plurality of wing patterns are defined by two perpendicular overlapping rectangular patterns.

4. The mask of claim 1, wherein an axis of the square pattern is oriented along an axis of the lithographic mask.

5. The mask of claim 1, wherein an axis of the square pattern is oriented at a 45 degree angle to an axis of the lithographic mask.

6. The mask of claim 1, wherein square feature is a contact in a semiconductor device.

7. A lithographic mask, comprising:
a rectangular pattern for printing a rectangular feature on a semiconductor wafer; and
a plurality of wing patterns positioned adjacent to each side of the rectangular pattern, wherein the plurality of wing patterns aid in the transfer of the rectangular pattern onto the semiconductor wafer.

8. The mask of claim 7, further comprising:
outriggers positioned adjacent to the rectangular pattern, wherein the outriggers aid in the transfer of the rectangular pattern.

9. The mask of claim 7, wherein the square pattern and the plurality of wing patterns are defined by two perpendicular overlapping rectangular patterns.

10. The mask of claim 7, wherein an axis of the rectangular pattern is oriented along an axis of the lithographic mask.

11. The mask of claim 7, wherein an axis of the rectangular pattern is oriented at a 45 degree angle to an axis of the lithographic mask.

12. The mask of claim 7, wherein the rectangular feature is a via in a semiconductor device.

13. A method of printing a semiconductor feature onto a semiconductor wafer, comprising:
placing a lithographic mask in a lithographic apparatus, wherein the lithographic mask comprises at least one pattern for printing a feature on the semiconductor wafer and a plurality of wing patterns positioned adjacent to each side of the at least one pattern; and
exposing the lithographic mask to polarized radiation to transfer the at least one pattern onto the semiconductor wafer.

14. The method of claim 13, wherein the polarized radiation comprises one of traverse electric field polarization, transverse magnetic field polarization, or azimuthal polarization.

15. The method of claim 13, wherein the at least one pattern is a square pattern or a rectangular pattern.

16. The method of claim 15, wherein the mask further comprises outriggers positioned adjacent to the at least one pattern.
